(19) United States
(12) Patent Application Publication
(10) Pub. No.: US 2013/0302536 A1
(43) Pub. Date: Nov. 14, 2013

(54) METHOD FOR DEPOSITING A TRANSPARENT BARRIER LAYER SYSTEM

(71) Applicants: Steffen Guenther, Dresden (DE); Bjoern Meyer, Dresden (DE); Steffen Straach, Dresden (DE); Thomas Kuehnel, Pirna (DE); Sebastian Bunk, Dresden (DE); Nicolas Schiller, Stolpen OT Helmsdorf (DE)

(72) Inventors: Steffen Guenther, Dresden (DE); Bjoern Meyer, Dresden (DE); Steffen Straach, Dresden (DE); Thomas Kuehnel, Pirna (DE); Sebastian Bunk, Dresden (DE); Nicolas Schiller, Stolpen OT Helmsdorf (DE)

(73) Assignee: FRAUNHOFER-GESELLSCHAFT ZUR FOERDERUNG DER ANGEWANDTEN FORSCHUNG E.V., Muenchen (DE)

(21) Appl. No.: 13/980,257

(22) PCT Filed: Feb. 15, 2012
(86) PCT No.: PCT/EP2012/052537

§ 371 Date: Jul. 17, 2013

(30) Foreign Application Priority Data
Apr. 18, 2011 (DE) 10 2011 017 404.4

(51) Int. Cl. C23C 16/30

(52) U.S. Cl. CPC C23C 16/30
USPC 427/575; 427/255.28; 427/255.394; 427/569

(57) ABSTRACT

The invention relates to a method for producing a transparent bather layer system, wherein in a vacuum chamber at least two transparent barrier layers and a transparent intermediate layer disposed between the two barrier layers are deposited on a transparent plastic film, wherein for deposition of the barrier layers aluminium is vaporised and simultaneously at least one first reactive gas is introduced into the vacuum chamber and wherein for deposition of the intermediate layer aluminium is vaporised and simultaneously at least one second reactive gas and a gaseous or vaporous organic component are introduced into the vacuum chamber.

### SPECIFICATION

The invention relates to a method for depositing a transparent layer system with a barrier effect against water vapor and oxygen.

### PRIOR ART

Electronically active materials, which are used in many different electronic assemblies, often have a high sensitivity to moisture and atmospheric oxygen. In order to protect these materials, it is known to encapsulate assemblies of this type. This occurs on the one hand by the direct deposition of a protective layer on the materials that are to be protected or by surrounding the assemblies using additional components. Thus, solar cells, for example, are often protected against moisture and other external influences by glass. In order to save weight and also achieve additional degrees of freedom with respect to the design, plastic films are also used for the encapsulation. Such plastic films must be coated for a sufficient protective effect. Therefore, at least one so-called permeation blocking layer (hereinafter also referred to as a barrier layer) is deposited on the plastic films.

Barrier layers oppose different permeating substances partially with a very different resistance. The permeation, under defined conditions, of oxygen (OTR) and water vapor (WVTR) through the substrates provided with the barrier layer is frequently used for the characterization of barrier layers (WVTR according to DIN 53122-2-A; OTR according to DIN 53380-3).

Because of the coating with a barrier layer, the permeation through a coated substrate is reduced compared to an uncoated substrate by a factor that can be in the single-digit range or many orders of magnitude. In addition to predefined barrier values, various other target parameters of a barrier layer are also often expected. An example hereof is optical, mechanical and technological-economical demands. Thus, barrier layers are often to be virtually completely transparent in the visible spectral range or beyond that. If barrier layers are used in layer systems, it is often advantageous if coating steps for applying individual parts of the layer system can be combined with one another.

To produce barrier layers, so-called PECVD methods (plasma enhanced chemical vapor deposition) are often used. These methods can be used when coating many different substrates for various layer materials. For example, it is known to deposit SiO₂ layers and Si₃N₄ layers at a thickness of 20 to 30 nm on 13 μm of PET substrates [A. S. da Silva Sobrinho et al., J. Vac. Sci. Technol. A 16(6), November/December 1998, p. 3190-3198]. At a working pressure of 10 Pa, permeation values of WVTR=0.3 g/m²d and OTR=0.5 cm³/m²d can be achieved in this manner.

When depositing SiOₓ for transparent barrier layers on PET substrates by means of PECVD, an oxygen barrier of OTR=0.7 cm³/m²d can be achieved [R. J. Nelson and H. Chatham, Society of Vacuum Coaters, 34th Annual Technical Conference Proceedings (1991) p. 113-117]. In another source, permeation values on the scale of WVTR=0.3 g/m²d and OTR=0.5 cm³/m²d are specified for this technology for transparent barrier layers on PET substrates [M. Izu, B. Dotter, S. R. Ovshinsky, Society of Vacuum Coaters, 36th Annual Technical Conference Proceedings (1993) p. 333-340].

Disadvantages of the known PECVD methods are, above all, that only relatively small barrier effects are achieved. This makes such barrier layers unappealing, in particular for the encapsulation of electronic products. A further disadvantage is the high working pressure that is necessary for the execution of such a method. If a coating step of this type is to be integrated into complex production sequences on vacuum equipment, a high expenditure for pressure decoupling measures possibly becomes necessary. A combination with other coating processes usually becomes uneconomical for this reason.

Furthermore, it is known to apply barrier layers by means of sputtering. Sputtered individual layers often exhibit better barrier properties than PECVD layers. For sputtered AlNO on PET, WVTR=0.2 g/m²d and OTR=1 cm³/m²d are stated for example as permeation values [Thin Solid Films 388 (2001) 78-86]. In addition, numerous other materials are known which are used for producing transparent barrier layers in particular by means of reactive sputtering. However, the layers produced in this manner also have barrier effects that are too small. An additional disadvantage of layers of this type is their low mechanical loadability. Damages which occur due to technologically unavoidable stresses during further processing or use usually lead to a clear deterioration of the barrier effect. This often renders sputtered individual layers unusable for barrier applications. A further disadvantage of sputtered layers is their high costs, which are caused by the low productivity of the sputtering process.

Furthermore, it is known to vapor deposit individual layers as barrier layers. Using such PVD methods, various materials can also be directly or reactively deposited on many different substrates. For barrier applications, for example, the reactive vapor coating of PET substrates with Al₂O₃ is known [Surface and Coatings Technology 125 (2000) 354-360]. Here, permeation values of WVTR=1 g/m²d and OTR=5 cm³/m²d are achieved. This barrier effect is likewise much too small to be able to use materials coated in this manner as barrier layers for electronic products. They are often mechanically even less loadable than sputtered individual layers. However, the very high coating rates that are achieved by vaporization processes are advantageous. These rates are typically greater than those achieved by sputtering by a factor of 100.

It is likewise known, when depositing barrier layers, to use magnetron plasmas for a plasma polymerization (EP 0 815 283 B1); [So Fujimaki, H. Kashiwase, Y. Kokaku, Vacuum 59 (2000) p. 657-664]. This concerns PECVD processes that are directly sustained by the plasma of a magnetron discharge. An example hereof is the use of a magnetron plasma for PECVD coating to deposit layers with a carbon framework, wherein CH₄ serves as a precursor. However, layers of this type also have a barrier effect that is merely insufficient for high demands.

Furthermore, it is known to apply barrier layers or barrier layer systems in multiple coating steps. One method from this class is the so-called PML (polymer multilayer) process (1999 Materials Research Society, p. 247-254); [J. D. Affinito, M. E. Gross, C. A. Coronado, G. L. Graff, E. N. Greenweil and P.M. Martin, Society of Vacuum Coaters, 39th Annual Technical Conference Proceedings (1996) p. 392-397].

In the PML process, a liquid acrylate film is applied to a substrate by means of a vaporizer, which film is cured using electron-beam technology or UV irradiation. This film itself does not have a particularly high barrier effect. Subsequently, a coating of the cured acrylate film occurs using an oxidic intermediate layer, to which an acrylate film is in turn applied. If needed, this procedure is repeated multiple times. The permeation values of a layer stack produced in this manner, that is, of a combination of individual oxidic barrier layers with acrylate layers as intermediate layers, is below the measuring limit of conventional permeation-measuring devices. Here, disadvantages occur above all in the necessary use of costly industrial manufacturing equipment. In addition, a liquid film first forms on the substrate, which film must be cured. This leads to an increased contamination of the equipment, which shortens service cycles. In coating processes of this type, the intermediate layer functioning as a barrier layer is usually produced by means of magnetron sputtering. Here, it is also disadvantageous that a comparatively slow process is resorted to due to the use of sputtering technology. Thus, very high product costs result which stem from the low productivity of the technologies used.

It is known that the mechanical stability of inorganic vaporized layers can be improved if an organic modification is performed during the vaporization. The installation of organic components thereby occurs in the inorganic matrix that forms during the layer growth. Because of the installation of these additional components in the inorganic matrix, an increase in the elasticity of the entire layer evidently results, which markedly reduces the risk of ruptures in the layer. In this context, a combination process that combines an electron-beam vaporization of SiOₓ with the admission of HMDSO (DE 195 48 160 C1) should be named representatively, as at least suitable for barrier applications. However, the low permeation rates necessary for electronic components cannot be achieved using layers produced in this manner.

### PROBLEM

The invention is therefore based on the technical problem of creating a method with which the disadvantages from the prior art are overcome. In particular, a transparent barrier layer system with a high blocking effect against oxygen and water vapor, as well as a high coating rate, is to be producible using the method.

The solution to the technical problem follows from the subject matter with the features of claim 1. Further advantageous embodiments follow from the dependent claims.

For a method for producing a transparent barrier layer system according to the invention, at least two transparent barrier layers are deposited on a transparent plastic film inside a vacuum chamber, between which barrier layers a transparent intermediate layer is also embedded. For the deposition of the barrier layers, aluminum is vaporized inside the vacuum chamber in a reactive process by admitting at least one additional reactive gas, such as oxygen or nitrogen for example, into the vacuum chamber simultaneously during the vaporization of the aluminum.

The intermediate layer is likewise deposited by reactively vaporizing aluminum inside the vacuum chamber during a simultaneous admission of at least one reactive gas, such as oxygen or nitrogen for example. Additionally, a gaseous or vaporous organic component is also simultaneously admitted into the vacuum chamber in the deposition of the intermediate layer during the vaporization of the aluminum. Thus, in addition to the main component aluminum, organic components are also embedded in the deposition of the intermediate layer during the layer construction. The intermediate layer is therefore an aluminum-containing layer with organic components or, expressed in other words, an organically modified aluminum-containing layer. For example, precursors and in particular precursors containing silicon, such as HMDSO, HMDSN or TEOS, are suitable as an organic component that is admitted into the vacuum chamber in the form of gas or vapor.

A transparent barrier layer system deposited using the method according to the invention is characterized by a high blocking effect against water vapor and oxygen, as well as a high loadability under bending stress and tensile stress, wherein the layer system can also still be deposited with the high coating rates known for the vaporization. Because of these properties, barrier layer systems deposited according to the invention are, for example, suitable for the encapsulation of components in the production of solar cells, of OLEDs or electronically active materials.

The high blocking effect of the layer system deposited according to the invention against water vapor and oxygen is mainly accounted for in that an organically modified aluminum-containing layer causes a growth stop of layer defects of a barrier layer deposited thereunder by reactive aluminum vaporization. It is known that, once they have occurred, layer defects that arise during the reactive vaporization of aluminum often grow with the layer growth through the remaining layer thickness. The organically modified aluminum-containing intermediate layer deposited between the barrier layers in the method according to the invention is able to cover the layer defects of the barrier layer lying thereunder, such that these defects are not extended during the growing of the second barrier layer lying above the intermediate layer. Thus, a high barrier effect or blocking effect against water vapor and oxygen can be achieved using a layer system deposited according to the invention. The blocking effect against water vapor and oxygen can, up to a certain degree, be further increased if barrier layer and intermediate layer are alternatingly deposited after one another multiple times.

For the vaporization of the aluminum during the deposition of a barrier layer or an intermediate layer, boat vaporizers or electron-beam vaporizers known for the vaporization can be used. The deposition of barrier layer and/or intermediate layer can also be assisted by a plasma that penetrates the space between aluminum vaporizer and a plastic film substrate that is to be coated. This is in particular advantageous for the deposition of the intermediate layer, as the acting of a plasma on a gaseous or vaporous organic component accelerates the splitting of this component and therefore facilitates the embedding of organic components in the intermediate layer. Here, in particular, hollow cathode plasmas or microwave plasmas are suitable as plasmas.

### EXEMPLARY EMBODIMENT

The invention is explained in greater detail below by means of an exemplary embodiment. For a 650-mm-wide and 75-um-thick plastic film of the material PET, the blocking effect against water vapor is to be increased. For this purpose, the plastic film is coated with different aluminum-containing layers or layer systems in a vacuum chamber in three test series.

To vaporize the aluminum, eight known boat vaporizers are used which are arranged below the plastic film that is to be coated distributed at a uniform distance across the width of the plastic film. In all three test series, the vaporization of the aluminum occurs at a vaporization rate of 2 g/min for each boat vaporizer, wherein the plastic film is moved respectively past the boat vaporizer at a belt speed of 50 m/min. All layers are deposited in a plasma-assisted manner. Four hollow cathodes, which are likewise arranged distributed at a uniform distance across the width of the plastic film, produce a plasma that penetrates on the one side the space between the boat vaporizers and on the other side the plastic film that is to be coated. The four hollow cathodes are thereby fed by an electric current of respectively 300 A.

In a first test, only one barrier layer is to be deposited on the plastic substrate by means of a reactive vaporization of aluminum. As a reactive gas, oxygen is used which here and also in the subsequent tests flows into the vacuum chamber at respectively 12.3 slm. For the parameters indicated, an aluminum oxide layer with a layer thickness of 70 nm is deposited on the plastic film. For this compound of plastic film and aluminum oxide layer, a barrier effect against water vapor (WVTR in [g/m2/d]) of 0.85 is measured.

In a second test, the 70-nm-thick barrier layer of aluminum oxide known from the first test is first applied to the plastic film. Then, the plastic film provided with the barrier layer is subsequently guided through the vacuum chamber one more time and an organically modified aluminum oxide layer is deposited. Here, the parameters of the aluminum vaporization process are the same as for the deposition of the barrier layer. Additionally, aside from the reactive gas oxygen, the organic component HDMSO is also admitted into the vacuum chamber at 950 sccm during the vaporization. Because of the effect of the plasma on the HMDSO, the HMDSO is split into components which are embedded in the second aluminum oxide layer. In this manner, an 85-nm-thick aluminum oxide layer with organic components or, expressed in other words, an organically modified aluminum oxide layer now forms over the barrier layer of aluminum oxide. For the compound of plastic film, aluminum oxide layer and organically modified aluminum oxide layer, a barrier effect against water vapor (WVTR in [g/m2/d]) of likewise 0.85 was measured.

The barrier effect has thus not been improved over the first test. However, compared to the first test, it was possible to exert a higher tensile stress on the coated plastic layer until cracks in the layer system became visible.

In the third test, a second barrier layer was also applied according to the invention to the organically modified aluminum oxide layer in contrast to the second test, which organically modified layer was deposited using the same parameters as the first barrier layer from the first and second test. The result of the third test accordingly comprised a 75-μm-thick PET film, two 70-nm-thick barrier layers of aluminum oxide, between which an 85-nm-thick organically modified aluminum oxide layer is located. For this compound, it was possible to measure a barrier effect against water vapor (WVTR in [g/m2/d]) of 0.45. Compared to the first and second test, the layer system stemming from the third test had an improved blocking effect against water vapor. The loadability under a tensile loading was comparable to that of the second test. The barrier layer system from the third test deposited according to the method according to the invention thus has a high blocking effect against water vapor and also a good loadability with respect to a tensile loading.

At this juncture, it should be mentioned that the previously indicated values of physical sizes with regard to the reactive aluminum vaporization are only provided by way of example and do not limit the method according to the invention. For the reactive vaporization of the aluminum according to the method according to the invention, all other values of physical sizes that are known from the prior art for the reactive aluminum vaporization can also be applied.

1. Method for producing a transparent barrier layer system, wherein at least two transparent barrier layers and one transparent intermediate layer arranged between the two barrier layers are deposited on a transparent plastic film in a vacuum chamber, characterized in that aluminum is vaporized for the deposition of the barrier layers and at least one first reactive gas is simultaneously admitted into the vacuum chamber, and in that aluminum is vaporized for the deposition of the intermediate layer and at least one second reactive gas and a gaseous or vaporous organic component are simultaneously admitted into the vacuum chamber.

2. Method according to claim 1, characterized in that the barrier layer and the second layer are alternatingly deposited multiple times.

3. Method according to claim 1, characterized in that oxygen and/or nitrogen is used as a first and/or second reactive gas.

4. Method according to claim 1, characterized in that the deposition of the barrier layer and/or the deposition of the second layer occurs in the vacuum chamber in the presence of a plasma.

5. Method according to claim 4, characterized in that a hollow cathode plasma or a microwave plasma is used as a plasma.

6. Method according to claim 1, characterized in that a precursor containing silicon is admitted into the vacuum chamber as a gaseous or vaporous organic component.

7. Method according to claim 6, characterized in that HMDSO, HMDSN or TEOS is used as a precursor.
